(19) United States
(12) Patent Application Publication
(10) Pub. No.: US 2009/0186281 A1
(43) Pub. Date: Jul. 23, 2009

(54) METHOD FOR PRODUCING SILICON-CONTAINING COMPLEX OXIDE SOL, METHOD FOR PRODUCING SILICON-CONTAINING HOLOGRAM RECORDING MATERIAL, AND HOLOGRAM RECORDING MEDIUM

(75) Inventors: Atsuko KOSUDA, Tokyo (JP); Naoki HAYASHIDA, Tokyo (JP); Jiro YOSHINARI, Tokyo (JP); Toshimi FUKUI, Shimogyo-ku (JP); Junko NAKAMOTO, Shimogyo-ku (JP); Saori YAMAKI, Shimogyo-ku (JP); Heidy Hodex Visbal MENDOZA, Shimogyo-ku (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TDK CORPORATION, Tokyo (JP)

(21) Appl. No.: 12/356,979

(22) Filed: Jan. 21, 2009

(30) Foreign Application Priority Data
Jan. 23, 2008 (JP) 2008-013092

(51) Int. Cl. G03F 7/00

(52) U.S. Cl. 430/2

(57) ABSTRACT

The present invention provides a method for producing a homogeneous complex oxide sol comprising Si and a metal other than Si as metal elements, and a method for producing a Si-containing hologram recording material using a homogeneous complex oxide sol. A method for producing a complex oxide sol comprising Si and a metal other than Si as metal elements, the method comprising: mixing a silanol compound with an alkoxide compound of a metal other than Si so that the silanol compound is reacted with the alkoxide compound, thereby yielding a precursor of a complex oxide, and adding water to the complex oxide precursor so as to hydrolyze an alkoxyl group bonded to the metal other than Si, and then making the resulting hydrolysate undergo a condensation reaction, thereby forming a complex oxide. A hologram recording medium (11) having a hologram recording layer (21) comprising the hologram recording material obtained by the production method.

### BACKGROUND OF THE INVENTION

1. Field of the Invention

The present invention relates to a method for producing a silicon-containing complex oxide sol, and to a silicon-containing complex oxide sol obtained by the production method. Moreover, the present invention relates to a method for producing a silicon-containing hologram recording material which uses the above-described method for producing the silicon-containing complex oxide sol, and to a hologram recording medium having a hologram recording layer comprising the hologram recording material obtained by the production method. The present invention relates particularly to a hologram recording material suitable for record and reproduction by use of not only a green laser light but also a blue laser light, a method for producing the same, and a hologram recording medium having a hologram recording layer comprising the hologram recording material.

2. Disclosure of the Related Art

The use of films derived from the sol-gel process has been spreading in order to modify the property of a polymer material surface or form an organic-inorganic hybrid film. When a metal oxide is formed by the sol-gel process, a hydrolyzable-group-containing compound of the corresponding metal, for example, an alkoxide compound of the metal is used as a starting material to conduct hydrolysis and polycondensation reaction in an appropriate solvent in the presence of an acid catalyst or alkaline catalyst, thereby yielding a liquid sol, and then the polycondensation reaction is further advanced to turn the sol into a wet gel of the metal oxide. Thereafter, the gel is turned into a dry gel if desired. In the sol-gel process, a sol can be molded, or a sol is applied onto a substrate, thereby making it possible to form a gel film. Alternatively, a gel fiber can be formed by spinning, and various molded products can be produced by molding. In such a way, the sol-gel process advances at low temperature; thus, the process is an excellent process.

When an alkoxide compound of titanium is used as a starting material in the sol-gel process, an oxide of titanium, TiO₂, can be obtained. TiO₂ has a high refractive index so as to be optically advantageous. Moreover, TiO₂ is used for surface modification since TiO₂ has a photocatalytic effect.

When an alkoxide compound of silicon and an alkoxide compound of a metal other than silicon, such as titanium, zirconium, tantalum, tin and aluminum, are used as starting materials in a sol-gel process, a complex oxide which contains Si and the metal other than Si as metal elements is obtained.

In a sol-gel process, however, an alkoxide compound of silicon is lower in a hydrolysis rate than an alkoxide compound of a metal other than silicon. Therefore, there is a problem that the hydrolysis and the polycondensation reaction of the alkoxide compound of the metal other than silicon proceed rapidly, so that an oxide of the metal other than silicon will aggregate. For this reason, a method for producing a homogeneous complex oxide sol containing silicon and a metal other than silicon, such as titanium, zirconium, tantalum, tin, zinc and aluminum as metal elements is demanded.

Examples of the property required for a volume hologram recording material include high refractive index change at the time of recording, high sensitivity, low scattering, environment resistance, durability, low dimensional change, and high multiplicity. About holographic memory record using a green laser, various reports have been made hitherto as follows.

For example, JP-A-2003-84651 discloses a hologram recording material comprising a compound having one or more polymerizable functional groups (functional compound), a photopolymerization initiator, and inorganic fine particles. The publication exemplifies, as the inorganic fine particles, a metal oxide, a metal nitride, a metal carbide, a semiconductor, or a simple substance of metal, and discloses that in order to disperse the particles evenly, it is preferred to chemically modify the surface of the fine particles at the time of producing the particles, or add a dispersant to the fine particles after producing the particles (paragraphs [0032] to [0033]).

JP-A-2005-77740 discloses a hologram recording material comprising metal oxide particles, a polymerizable monomer and a photopolymerization initiator wherein the metal oxide particles are treated with a surface treating agent in which a hydrophobic group and a functional group which can undergo dehydration-condensation with a hydroxyl group on the surface of the metal oxide particles are bonded to a metal atom; and the metal atom is selected from the group consisting of titanium, aluminum, zirconium, and chromium.

JP-A-2005-99612 discloses a hologram recording material comprising a compound having one or more polymerizable functional groups, a photopolymerization initiator, and colloidal silica particles.

JP-A-2005-321674 discloses a hologram recording material comprising: an organometallic compound at least containing at least two kinds of metals (Si and Ti) , oxygen, and an aromatic group, and having an organometallic unit wherein two aromatic groups are directly bonded to one metal (Si); and a photopolymerizable compound.

JP-A-2007-156452 discloses a hologram recording material comprising: an organometallic compound at least containing at least two kinds of metals (Si and Ti) , oxygen, and an aromatic group, and having an organometallic unit wherein two aromatic groups are directly bonded to one metal (Si); metal oxide fine particles; and a photopolymerizable compound.

The above-mentioned publications disclose holographic memory record using a green laser, but do not disclose holographic memory record using a blue laser. Also for hologram recording material, there is a demand for a method for producing a complex oxide sol that contains silicon and a metal other than silicon, such as titanium, zirconium, tantalum, tin, zinc and aluminum, as metal elements which exhibits no absorption in the blue laser wavelength region, the complex oxide sol being so homogeneous that no scatter due to complexing occurs and the complex oxide sol having a particle diameter of 10 nm or less.

### SUMMARY OF THE INVENTION

An object of the present invention is to provide a method for producing a homogeneous complex oxide sol comprising silicon and a metal other than silicon as metal elements, and a silicon-containing complex oxide sol obtained by the production method.

Another object of the present invention is to provide a method for producing a silicon-containing hologram recording material using a homogeneous complex oxide sol, and a hologram recording medium having a hologram recording layer comprising a hologram recording material obtained by the production method. Particularly, an object of the present invention is to provide a hologram recording medium suitable for volume hologram recording, which is capable of attaining a high refractive index change, a high flexibility, a high sensitivity, a low scattering property, a high environment resistance, a high durability, a low dimension change (a low shrinkage), and a high multiplicity in holographic memory recording using a blue laser as well as a green laser.

In the above-described JP-A-2005-321674 and JP-A-2007-156452, diphenyldimethoxysilane and a oligomer (decamer) of titanium butoxide having a deteriorated reactivity as Ti alkoxide are used in the sol-gel process. The present inventors have made investigations, so as to find out that when a blue laser is used to make a holographic memory record in the hologram recording medium disclosed in JP-A-2005-321674, the light transmittance thereof falls so that good holographic memory recording characteristics cannot be obtained. It has also been understood that the fall in the light transmittance results from coloration of a metal oxide matrix containing Ti as a constituent metal element when the matrix is formed by the sol-gel process. When a light transmittance falls, holograms (interference fringes) are unevenly formed in the recording layer along the thickness direction of the recording layer so that scattering-based noises and the like are generated. It has been found out that in order to obtain good hologram image characteristics, it is necessary that the medium has a light transmittance of 50% or more.

A light transmittance of a hologram recording layer depends on a thickness thereof. As the thickness of the recording layer is made smaller, the light transmittance is improved; however, the widths of diffraction peaks obtained when reproducing light is irradiated into a recorded pattern become larger so that separability between adjacent diffraction peaks deteriorates. Accordingly, in order to obtain a sufficient SN ratio (Signal to Noise ratio) , it is indispensable to make a shift interval (an angle or the like) large when multiple record is made. For this reason, a high multiplicity cannot be attained. In the use of a hologram recording medium in any recording system, the thickness of its recording layer is required to be at lowest 100 μm in order to attain holographic memory recording characteristics for ensuring a high multiplicity.

The present invention includes the following inventions.

(1) A method for producing a complex oxide sol comprising Si and a metal other than Si as metal elements, the method comprising:

mixing a silanol compound with an alkoxide compound of a metal other than Si so that the silanol compound is reacted with the alkoxide compound, thereby yielding a precursor of a complex oxide, and

adding water to the complex oxide precursor so as to hydrolyze an alkoxyl group bonded to the metal other than Si, and then making the resulting hydrolysate undergo a condensation reaction, thereby forming a complex oxide.

(2) The method for producing the complex oxide sol according to the above-described (1), wherein the metal other than Si is selected from the group consisting of Ti, Zr, Ta, Sn, Zn and Al.
(3) The method for producing the complex oxide sol according to the above-described (1) or (2), wherein neither acid catalyst nor alkaline catalyst is used during the hydrolysis.
(4) The method for producing the complex oxide sol according to anyone of the above-described (1) to (3), wherein the silanol compound is represented by the following general formula (I)

(R₁) (R₂)Si(OH)₂ (I)

wherein R₁ and R₂ may be the same or different and each represents an alkyl group which may have a substituent or an aryl group which may have a substituent, provided that at least one of the R₁ and the R₂ is an aryl group which may have a substituent.

(5) The method for producing the complex oxide sol according to anyone of the above-described (1) to (4), the method further comprising:

coordinating a complexing ligand to the alkoxide compound of the metal other than Si,

before the mixing of the silanol compound with the alkoxide compound of the metal other than Si, or after the mixing of the silanol compound with the alkoxide compound of the metal other than Si and before the addition of water.

In the present specification, a complexing ligand is a ligand which is capable of forming a complex with a metal atom by coordination. The complexing ligand is selected from the group consisting of, for example, β-dicarbonyl compounds, polyhydroxylated ligands, and α- or β-hydroxy acids.

(6) A complex oxide sol comprising Si and a metal other than Si as metal elements,

wherein the complex oxide sol is obtained by a method comprising:

mixing a silanol compound with an alkoxide compound of a metal other than Si so that the silanol compound is reacted with the alkoxide compound, thereby yielding a precursor of a complex oxide, and

adding water to the complex oxide precursor so as to hydrolyze an alkoxyl group bonded to the metal other than Si, and then making the resulting hydrolysate undergo a condensation reaction, thereby forming a complex oxide.

(7) A method for producing a hologram recording material comprising metal oxide fine particles containing an organic group and a photopolymerizable compound, the method comprising:

mixing a silanol compound with an alkoxide compound of a metal other than Si so that the silanol compound is reacted with the alkoxide compound, thereby yielding a precursor of a complex oxide,

adding water to the complex oxide precursor so as to hydrolyze an alkoxyl group bonded to the metal other than Si, and then making the resulting hydrolysate undergo a condensation reaction, thereby forming a complex oxide, and

mixing a photopolymerizable compound before, during or after the hydrolysis.

(8) The method for producing the hologram recording material according to the above-described (7), wherein the metal other than Si is selected from the group consisting of Ti, Zr, Ta, Sn, Zn and Al.
(9) The method for producing the hologram recording material according to the above-described (7) or (8), wherein neither acid catalyst nor alkaline catalyst is used during the hydrolysis.
(10) The method for producing the hologram recording material according to any one of the above-described (7) to (9), wherein the silanol compound is represented by the following general formula (I):

(R₁) (R₂)Si(OH)₂ (I)

wherein R₁ and R₂ may be the same or different and each represents an alkyl group which may have a substituent or an aryl group which may have a substituent, provided that at least one of the R₁ and the R₂ is an aryl group which may have a substituent.

(11) The method for producing the hologram recording material according to any one of the above-described (7) to (10), the method further comprising:

coordinating a complexing ligand to the alkoxide compound of the metal other than Si,

before the mixing of the silanol compound with the alkoxide compound of the metal other than Si, or after the mixing of the silanol compound with the alkoxide compound of the metal other than Si and before the addition of water.

(12) A hologram recording medium having a hologram recording layer comprising the hologram recording material obtained by the production method according to any one of the above-described (7) to (11).
(13) The hologram recording medium according to the above-described (12), wherein record/reproduction of the hologram recording medium are performed by use of a laser light having a wavelength of 350 to 450 nm.
(14) The hologram recording medium according to the above-described (12) or (13), wherein the hologram recording layer has a thickness of at least 100 μm.

In the method of the present invention for producing a complex oxide sol, a silanol compound is used for introduction of Si. A silanol compound is equivalent to a compound resulting from hydrolysis of an alkoxyl group of an alkoxide compound of Si. Such a silanol compound is mixed with an alkoxide compound of a metal other than Si, e.g. a metal selected from Ti, Zr, Ta, Sn, Zn and Al, and is reacted with the alkoxide compound to form a precursor of a complex oxide (a complex alkoxide), followed by hydrolysis and a polycondensation reaction. Therefore, a problem of aggregation of an oxide of a metal other than Si, caused by slow hydrolysis of conventionally used alkoxide compounds of Si, is solved, and it is possible to produce a homogeneous complex oxide sol containing Si and a metal other than Si. A homogeneous complex oxide sol is little in coloration or light scattering. Accordingly, the complex oxide sol obtained by the production method of the present invention is suitable for various articles about which the absorption of light in the blue region is not preferred, for example, an optical waveguide which is required to have low optical loss property, various coating films which are required to have transparency, and a metal oxide matrix material in a hologram recording material.

Furthermore, in the method for producing a complex oxide sol of the present invention, an acid catalyst and an alkaline catalyst are not always needed because of the weak acidity of a silanol group Si-OH of a silanol compound, and hydrolysis and a polycondensation reaction can be proceed in the absence of an acid catalyst or an alkaline catalyst. Therefore, it is possible to obtain a complex oxide sol containing neither any acid catalyst nor any alkaline catalyst. The applications of complex oxide sol containing neither any acid catalyst nor any alkaline catalyst become wide.

About the hologram recording material obtained by the production method of the present invention, the coloration and the light scattering thereof are significantly decreased, and the absorption of light having a wavelength in the blue region is slight. For this reason, by use of the hologram recording material of the present invention, provided is a hologram recording medium suitable for recording/reproducing using not only a green laser light but also a blue laser light.

### BRIEF DESCRIPTION OF THE DRAWINGS

FIG. 1 is a view illustrating a schematic cross section of a hologram recording medium produced in an example.

FIG. 2 is a plane view illustrating the outline of a hologram recording optical system used in the example.

### DETAILED DESCRIPTION OF THE INVENTION

First, the method of the present invention for producing a complex oxide sol containing Si and a metal other than Si as metal elements is described.

In the method of the present invention for producing a complex oxide sol, a silanol compound is first mixed with an alkoxide compound of a metal other than Si and is reacted with the alkoxide compound to form a precursor of a complex oxide (a complex alkoxide) . A silanol compound is a compound having a silanol group Si—OH, which compound is equivalent to a compound resulting from hydrolysis of an alkoxyl group of an alkoxide compound of Si.

The silanol compound used in the present invention is generally represented by

(R)ₓSi(OH)₄₋ₓ

wherein Rs may be the same or different when x represents 2 or 3, and R represents an alkyl group which may have a substituent or an aryl group which may have a substituent; and x represents 1, 2 or 3.

The silanol compound is preferably a disilanol compound represented by the following general formula (I):

(R₁)(R₂)Si(OH)₂ (I)

wherein R₁ and R₂ may be the same or different and represent an alkyl group which may have a substituent or an aryl group which may have a substituent, provided that at least one of the R₁ and the R₂ is an aryl group which may have a substituent.

The alkyl group represented by R₁ and R₂ is generally a lower alkyl group having 1 to 4 carbon atoms, and examples thereof include a methyl group, an ethyl group, a propyl group, an isopropyl group, a butyl group, an isobutyl and a sec-butyl group. Examples of the aryl group represented by R₁ and R₂ include a phenyl group. The alkyl group and the aryl group may have a substituent. Examples of such a substituent include a fluorine atom.

Specific examples of the disilanol compound include diphenyldisilanol, phenylmethyldisilanol and phenylethyldisilanol.

A monosilanol (x=3) such as trimethylsilanol can be used for adjusting the molecular weight because a polymerization reaction is stopped if a monosilanol is present.

The metal other than Si is not particularly restricted and may be selected from the group consisting of Ti, Zr, Ta, Sn, Zn and Al. Specific examples of the alkoxide compound of a metal other than Si include, not particularly limited to, alkoxide compounds of titanium, such as tetra-n-propoxytitanium [Ti(O-nPr)₄], titanium tetraisopropoxide [Ti(O-iPr)₄] and titanium tetra-n-butoxide [Ti(O-nBu)₄]; alkoxide compounds of tantalum, such as tantalum pentaethoxide [Ta(OEt)₅] and tantalum tetraethoxide pentanedionate [Ta(OEt)₄(C₅H₇O₂)]; alkoxide compounds of zirconium, such as zirconium tetra-tert-butoxide [Zr(O-tBu)₄] and zirconium tetra-n-butoxide [Zr(O-nBu)₄]; alkoxide compounds of tin, such as tin tetra-tert-butoxide [Sn(O-tBu)₄] and tin tetra-n-butoxide [Sn(O-nBu)₄]; alkoxide compounds of zinc, such as zinc diethoxide [Zn(OEt)₂] and zinc dimethoxyethoxide [Zn(OC₂H₄—OCH₃)₂]; alkoxide compounds of aluminum, such as aluminum tri-isopropoxide [Al(O-iPr)₃], aluminum tri-tert-butoxide [Al(O-tBu)₃], aluminum tri-sec-butoxide [Al(O-sBu)₃] and aluminum tri-n-butoxide [Al(O-nBu)₃]. Metal alkoxide compounds besides these examples may be used.

Further, oligomers of metallic alkoxide compounds, which correspond to partially hydrolytic condensates of metallic alkoxide compounds, may be also employed. For example, titanium butoxide oligomers, which correspond to partially hydrolytic condensates of titanium tetrabutoxide, may be employed.

The blended amounts of the silanol compound and the alkoxide compound of the metal other than Si may be determined appropriately depending upon the intended use so that, for example, a desired refractive index can be obtained.

It is preferable to mix the silanol compound with the alkoxide compound of the metal other than Si at a temperature within the range from room temperature to the boiling point of the solvent used. The reaction time after the mixing is preferably 0.5 to 1 hour. It is also effective to mix both of the reactants at room temperature, then increase the reaction temperature with stirring, and subsequently continue stirring. While the reaction temperature is preferably a temperature from room temperature (25° C.) to the boiling point of the solvent used, it is preferable, for example, to heat at about 70 to about 80° C.

As a result of this mixing-stirring treatment, a bimetallic alkoxide (a complex alkoxide) is formed between the reactants. For example, when (R₁)(R₂)Si(OH)₂ is used as the silanol compound and titanium tetraalkoxide [Ti(OR′)₄] (wherein R′ is an alkyl group) is used as the alkoxide compound of the metal other than Si, a bimetallic alkoxide such as

HO—Si (R₁)(R₂)—O—Ti—(OR′)₃ (II)

is formed.

If an alkoxide compound of two metals other than Si is used, a trimetallic alkoxide is formed. The formation of a complex alkoxide gives a more homogeneous complex oxide sol.

The mixing is preferably performed in a solvent the same as that to be used for the following sol-gel reaction. Examples of such a solvent include alcohols such as methanol, ethanol, 1-propanol, isopropanol, 1-butanol, 2-buthanol, tert-butanol and 1-methoxy-2-propanol; ethers such as diethyl ether, dioxane, dimethoxyethane and tetrahydrofuran; N-methyl pyrrolidone, acetonitrile, N,N-dimethylformamide, N,N-dimethylacetamide, dimethyl sulfoxide, acetone and benzene. A suitable solvent may be selected from these. Alternatively, a mixture of these may be used. It is better not to use water as a solvent. If water is used, hydrolysis of the alkoxide compound of a metal other than Si occur before completion of the reaction of the silanol compound and the alkoxide compound of the metal other than Si. Thus, a precursor of a complex oxide (a complex alkoxide) is obtained.

Next, water is added to the precursor of the complex oxide, so that an alkoxyl group bonded to the metal other than Si is hydrolyzed. Then, the resulting hydrolysate is caused to undergo a condensation reaction, so that a complex oxide is obtained.

The hydrolysis and the polymerization reaction can be carried out by the same operation under the same conditions as in known sol-gel process. For example, the reactions can be carried out by stirring a liquid of the complex oxide precursor in the presence of water. While the amount of the solvent is not particularly limited, it is preferably adjusted at 10 to 1000 parts by weight with respect to 100 parts by weight of the starting materials of the silanol compound and the metallic alkoxide compound in total. The added amount of water is preferably 1 to 10 molar times based on the amount of the metal alkoxide compound as a starting material. If the added amount of water is less than 1 molar time based on the amount of the metal alkoxide compound, a polymerization reaction proceed insufficiently, so that many alkoxyl groups remain. On the other hand, if water is added at an amount more than 10 molar times based on the amount of the metal alkoxide compound, it does not have a great effect on reduction in the amount of alkoxyl groups which remain. Therefore, water of not more than 10 molar times is enough.

In the hydrolysis and the polymerization reaction, while it is preferable to use neither any acid catalyst nor any alkaline catalyst, an acid catalyst or an alkaline catalyst may be suitably used.

Examples of the acid catalyst include: inorganic acids such as hydrochloric acid, sulfuric acid, nitric acid and phosphoric acid; organic acids such as formic acid, acetic acid, trichloroacetic acid, trifluoroacetic acid, propionic acid, methanesulfonic acid, ethanesulfonic acid, and p-toluenesulfonic acid; and the like.

The hydrolysis polymerization reaction can be generally conducted at room temperature, which depends on the reactivity of the silanol compounds and the metal alkoxide compounds. The reaction can be conducted at a temperature of about 0 to 150° C., preferably at a temperature of about room temperature to 50° C. The reaction time may be appropriately determined, correspondingly to the relationship with the reaction temperature. The time is about 0.1 to 240 hours. The reaction may be conducted in an inert atmosphere such as nitrogen gas, or may be conducted under a reduced pressure of about 0.5 to 1 atom while the alcohol produced by the polymerization reaction is removed.

The alkoxide compound of the metal other than Si shows, in a sol-gel process, a hydrolysis rate is greater than an alkoxide compound of Si. Therefore, using an alkoxide compound of Si in the synthesis of a metal oxide (complex oxide) as used conventionally leads to a problem that hydrolysis and a polycondensation reaction of the alkoxide compound of a metal other than Si proceed rapidly and an oxide of a metal other than Si aggregates. According to the present invention, a complex oxide precursor (a complex alkoxide) is formed first from a silanol compound and an alkoxide compound of a metal other than Si by using the silanol compound without using any Si alkoxide compounds, and then the complex alkoxide is subjected to hydrolysis and a polycondensation reaction. Therefore, the polycondensation reaction proceeds moderately, so that aggregation of oxides of other metals is inhibited. Therefore, a homogeneous complex oxide sol containing Si and a metal other than Si can be produced.

Furthermore, in the method for producing a complex oxide sol of the present invention, an acid catalyst and an alkaline catalyst are not always needed because of the weak acidity of a silanol group Si—OH of a silanol compound, and hydrolysis and a polycondensation reaction can be proceed in the absence of an acid catalyst or an alkaline catalyst. Therefore, it is possible to obtain a complex oxide sol containing neither acid catalyst nor alkaline catalyst.

In the present invention, it is also preferable that the method further comprises a step of coordinating a complexing ligand to the alkoxide compound of the metal other than Si, before the mixing of the silanol compound with the alkoxide compound of the metal other than Si, or after the mixing of the silanol compound with the alkoxide compound of the metal other than Si and before the addition of water.

In the present invention, because a silanol compound is used and a precursor of a complex oxide (a complex alkoxide) is formed first from the silanol compound and the alkoxide compound of the metal other than Si, and then the complex alkoxide is subjected to hydrolysis and a polycondensation reaction as described previously, no aggregation of an oxide of the metal other than Si occurs. In order to reduce the absorption of light in the blue region by the resulting complex oxide, however, it is preferable to coordinate a complexing ligand to an alkoxide compound of the metal other than Si (Ti, Zr, Ta, Sn, Zn or Al). In this case, in the complex oxide obtained, the complexing ligand is coordinated to at least one portion of the metal atom other than Si (i.e. Ti, Zr, Ta, Sn, Zn or Al).

As a complexing ligand, the so-called chelate ligand maybe used. Examples thereof include β-dicarbonyl compounds, polyhydroxylated ligands, α- or β-hydroxy acids, and ethanolamines. Examples of the β-dicarbonyl compounds include β-diketones such as acetylacetone (AcAc) and benzoylacetone, and β-ketoesters such as ethyl acetoacetate (EtAcAc) . Examples of the polyhydroxylated ligands include glycols (in particular, 1,3-diol type glycols such as 1,3-propanediol or 2-ethyl-1,3-hexanediol) . Examples of the α- or β-hydroxy acids include lactic acid, glyceric acid, tartaric acid, citric acid, tropic acid, and benzilic acid. Other examples of the ligand include oxalic acid.

As described above, when a mixture of the alkoxide compound of Si and the alkoxide compound of the metal (such as Ti, Zr, Ta, Sn, Zn and Al) other than Si is subjected to a sol-gel reaction, the alkoxide compound of Si is generally small in rates of hydrolysis and polymerization reaction and the alkoxide compound of the metal other than Si is large in rates of hydrolysis and polymerization reaction. As a result, an oxide of the metal other than Si aggregates so that a homogeneous sol-gel reaction product cannot be obtained. The present inventors have made investigations to find out that in the case of modifying an alkoxide compound of the metal other than Si chemically with a complexing ligand by coordinating the complexing ligand to the metal other than Si, the hydrolysis and polymerization reaction thereof can be appropriately restrained to yield a homogeneous sol-gel reaction product from a mixture of the metal other than Si with an alkoxide compound of Si, even if the alkoxide compound of Si is used. Accordingly, in the present invention, a more homogeneous sol-gel reaction product can be obtained by coordinating the complexing ligand to the alkoxide compound of the metal other than Si.

In the case of, for example, a Ti alkoxide compound, it is preferred to coordinate a glycol thereto, examples of the glycol including 1,3-propanediol, 1,3-butanediol, 2-methyl-1,3-propanediol, 2-ethyl-1,3-hexanediol, and 2-methyl-2,4-pentanediol.

It appears that the above-mentioned glycol (that is, 1,3-diol) is a polydentate ligand which coordinates easily to the Ti atom of the Ti alkoxide compound as a starting material so as to be filled into coordination positions of the Ti atom, so that the glycol prevents a different coordinating-compound from coordinating to the Ti atom in the sol-gel reaction and further the hydrolysis and polymerization reaction are restrained. The coordination of the glycol to the Ti alkoxide compound is preferably attained by mixing the Ti alkoxide compound such as titanium tetrabutoxide or titanium tetraethoxide with the glycol in a solvent such as ethanol orbutanol, for example, at room temperature, and then stirring the mixture. The solvent used in this case may be the same solvent used in the sol-gel reaction. In such a way, the Ti alkoxide compound to which the glycol is coordinated is prepared.

Further, in the case of Ti alkoxide compound, it is preferred to coordinate the polyalkylene glycol as a glycol to the Ti atom. Examples of the polyalkylene glycol include diethyleneglycol, triethyleneglycol, tetraethyleneglycol, dipropylene glycol, tripropylene glycol, and tetrapropylene glycol.

In the same manner as in the 1,3-diol, the above-mentioned polyalkylene glycol is easily coordinated to the Ti atom of the Ti alkoxide compound as a starting material to fill the coordination positions of the Ti atom, and hinders any different coordinating compound frombeing coordinatedto the Ti atom in the sol-gel reaction. The coordination of the polyalkylene glycol to the Ti alkoxide compound is preferably attained in the same way as the coordination of the 1,3-diol thereto. Out of the above-mentioned polyalkylene glycols, dipropylene glycol is preferred since the dipropylene glycol is high in coordinating ability and is easily available.

For example, in the case of the alkoxide compound of Zr, it appears that the hydrolysis and polymerization reaction are retarded by a matter that the complexing ligand is coordinated to Zr(OR)₄ wherein R represents an alkyl group to change the alkoxide compound to an alkoxide compound such as Zr(OR)₂(AcAc)₂ so that the number of alkoxy groups which can contribute to the hydrolysis and polymerization reaction decreases; and a matter that the reactivity of the alkoxy groups is retarded by a steric factor of the complexing ligand such as acetylacetone (AcAc) . The same matter would be true for the alkoxide compound of Ta, Ta(OR)₅.

The amount of the complexing ligand to be used is not particularly limited. Taking into consideration the above reaction retarding effect, however, it is preferable to determine the amount of the complexing ligand suitably on the basis of the amount of the alkoxide compound of the metal other than Si. If the alkoxide compound of the metal other than Si to which a complexing ligand is coordinated is available, it may be used for the present invention without execution of this step.

In the manner described above, a sol of a complex oxide of the present invention containing Si and a metal (M) other than Si as metal elements can be obtained. It is considered that the resulting complex oxide in the form of fine particles contains a linkage in which Si atoms are bonded to each other through an oxygen atom (Si—O—Si) and a linkage in which atoms of a metal (M) other than Si are bonded to each other through an oxygen atom (M-O-M) as well as a linkage in which a Si atom and an atom of a metal (M) other than Si are bonded to each other through an oxygen atom (Si—O-M) . It is considered that fine particles that are mainly composed of linkages in which Si atoms are bonded to each other through an oxygen atom (Si—O—Si) and that are free of atoms of a metal (M) other than Si, or fine particles that are mainly composed of linkages in which atoms of a metal (M) other than Si are bonded to each other through an oxygen atom (M-O-M) and that are free of Si atoms are also contained in the resulting sol of the complex oxide. That is, in this case, the complex oxide sol is in the form of a mixed sol containing fine particles made of a complex oxide of Si and a metal other than Si, fine particles made of a Si oxide, and fine particles made of an oxide of a metal other than Si.

Next, the method of the present invention for producing a hologram recording material, using the above-described method for producing a complex oxide sol, will be described.

A silanol compound is first mixed with an alkoxide compound of a metal other than Si and is reacted with the alkoxide compound to form a precursor of a complex oxide (a complex alkoxide).

The silanol compound is preferably a disilanol compound represented by the following general formula (I):

(R₁)(R₂)Si(OH)₂ (I)

wherein R₁and R₂may be the same or different and represent an alkyl group which may have a substituent or an aryl group which may have a substituent, provided that at least one of R₁ and R₂ is an aryl group which may have a substituent.

The alkyl group represented by R₁ and R₂ is generally a lower alkyl group having about 1 to about 4 carbon atoms, and examples thereof include a methyl group, an ethyl group, a propyl group, an isopropyl group, a butyl group, an isobutyl group and a sec-butyl group. Examples of the aryl group represented by R₁ and R₂ include a phenyl group. The alkyl group and the aryl group may have a substituent. Examples of such a substituent include a fluorine atom.

Specific examples of the disilanol compound include diphenyldisilanol, phenylmethyldisilanol and phenylethyldisilanol. Among these examples, diphenyldisilane is preferred.

If the silanol compound represented by the general formula (I) is used, a metal oxide matrix is formed in which an organic group has been introduced by a direct bond (silicon-carbon bond) between a silicon atom and a carbon atom of the organic group. Such an organic group-containing metal oxide matrix is preferred because the matrix has flexibility and compatibility with a photopolymerizable compound. That is, the metal oxide matrix has a constitution containing an organometallic compound.

Moreover, a silanol compound, such as tert-butyltrisilanol (x=1) and trimethylsilanol (x=3), may be suitably used besides a disilanol compound. A monosilanol such as trimethylsilanol (x=3) can be used for adjusting the molecular weight because a polymerization reaction is stopped if a monosilanol is present.

The metal other than Si is not particularly restricted and it may be selected from the group consisting of Ti, Zr, Ta, Sn, Zn and Al. Specific examples of the alkoxide compound of the metal other than Si include those the same as described above. Oligomers of metallic alkoxide compounds, which correspond to partially hydrolytic condensates of metallic alkoxide compounds, may be also employed. For example, titanium butoxide oligomers, which correspond to partially hydrolytic condensates of titanium tetrabutoxide, may be employed.

The blended amounts of the silanol compound and the alkoxide compound of the metal other than Si may be determined appropriately depending upon the intended design of a medium so that, for example, a desired refractive index can be obtained. For example, the blended amounts of the titanium alkoxide compound and the silanol compound are adjusted preferably at 0.1/1.0 to 10/1.0 in an atomic ratio Ti/Si so that a desired refractive index can be obtained. For other metals such as Zr, Ta, Sn, Zn and Al, the blended amounts of an alkoxide compound and a silanol compound may be determined appropriately.

It is preferable to mix the silanol compound with the alkoxide compound of the metal other than Si at a temperature within the range from room temperature to the boiling point of the solvent used. The reaction time after the mixing is preferably 0.5 to 1 hour. It is also effective to mix both of the reactants at room temperature, then increase the reaction temperature with stirring, and subsequently continue stirring. While the reaction temperature is preferably a temperature from room temperature (25° C.) to the boiling point of the solvent used, it is preferable, for example, to heat at about 70 to about 80° C.

As a result of this mixing-stirring treatment, a bimetallic alkoxide (complex alkoxide) is formed between the reactants. For example, when (R₁)(R₂)Si(OH)₂ is used as the silanol compound and titanium tetraalkoxide [Ti(OR′)₄] (wherein R′ is an alkyl group) is used as another metallic alkoxide compound, a bimetallic alkoxide such as

HO—Si(R₁)(R₂)—O—Ti—(OR′)₃ (II)

is formed.

If an alkoxide compound of two metals other than Si is used, a trimetallic alkoxide will be formed. The formation of a complex alkoxide gives a more homogeneous complex oxide sol.

The mixing is preferably performed in a solvent the same as that to be used for the following sol-gel reaction. Examples of such a solvent include those the same as described above. Thus, a precursor of a complex oxide (a complex alkoxide) is obtained.

Next, water is added to the precursor of the complex oxide, so that an alkoxyl group bonded to the metal other than Si is hydrolyzed. Then, the resulting hydrolysate is caused to undergo a condensation reaction, so that a complex oxide is obtained.

The hydrolysis and the polymerization reaction can be carried out by operations and under conditions the same as those used in the conventional sol-gel process. For example, the reactions can be carried out by stirring a liquid of the precursor of a complex oxide in the presence of water. While the amount of the solvent is not particularly limited, it is preferably adjusted at 10 to 1000 parts by weight with respect to 100 parts by weight of the starting materials of the silanol compound and the metallic alkoxide compound in total. The added amount of water is preferably 1 to 10 molar times based on the amount of the metal alkoxide compound as a starting material. If the added amount of water is less than 1 molar time based on the amount of the metal alkoxide compound, a polymerization reaction will not proceed sufficiently, so that many alkoxyl groups will remain. On the other hand, if water is added in an amount of more than 10 molar times based on the amount of the metal alkoxide compound, it does not have a great effect on reduction in the amount of alkoxyl groups that will remain. Therefore, water of not more than 10 molar times is enough.

In the hydrolysis and the polymerization reaction, while it is preferable to use neither any acid catalyst nor any alkaline catalyst, an acid catalyst or an alkaline catalyst may be suitably used.

Before, during or after the hydrolysis, a photopolymerizable organic compound, which will be described below, is mixed. The photopolymerizable organic compound may be mixed after the hydrolysis of the precursor of the complex oxide. Alternatively, it may be mixed either during the hydrolysis or before the hydrolysis. When being mixed after the hydrolysis, the photopolymerizable organic compound is preferably added and mixed while a sol-gel reaction system containing a metal oxide (a composite oxide) is in a sol state so that the photopolymerizable organic compound can be mixed uniformly. Moreover, mixing of a photopolymerization initiator or a photosensitizer may be also performed before, during or after the hydrolysis.

What is obtained is a hologram recording material liquid in which a photopolymerizable compound is uniformly mixed in a metal oxide (a complex oxide) matrix in a sol state. By applying the hologram recording material liquid onto a substrate, and further proceeding a drying of a solvent and a sol-gel reaction, a hologram recording material layer in a film form is obtained. Thus, a hologram recording material layer containing a photopolymerizable compound uniformly in a metal oxide matrix is produced.

In the present invention, it is also preferable that the method further comprises a step of coordinating a complexing ligand to the alkoxide compound of the metal other than Si, before the mixing of the silanol compound with the alkoxide compound of the metal other than Si, or after the mixing of the silanol compound and the alkoxide compound of the metal other than Si and before the addition of water. It is also preferable to use an commercially available alkoxide compound of a metal other than Si to which a complexing ligand has been coordinated. That is, a precursor of a complex oxide (complex alkoxide) is obtained from the silanol compound and the alkoxide compound of a metal other than Si to which a complexing ligand has been coordinated, or a precursor of a complex oxide (complex alkoxide) is formed from the silanol compound and the alkoxide compound of a metal other than Si and then a complexing ligand is coordinated to the precursor. By subjecting the resulting complex alkoxide in which the complexing ligand is coordinated to the metal other than Si to a sol-gel reaction, it is possible to retard hydrolysis and a polymerization reaction of an alkoxyl group of the metal other than Si and, as a result, a further uniform complex oxide matrix can be obtained. The particulars of the complexing ligand have been described above.

In the present invention, the photopolymerizable compound is a photopolymerizable monomer. As the photopolymerizable compound, a compound selected from a radical polymerizable compound and a cation polymerizable compound can be used.

The radical polymerizable compound is not particularly limited as long as the compound has in the molecule one or more radical polymerizable unsaturated double bonds. For example, a monofunctional and polyfunctional compound having a (meth)acryloyl group or a vinyl group can be used. The wording “(meth)acryloyl group” is a wording for expressing a methacryloyl group and an acryloyl group collectively.

Examples of the compound having a (meth) acryloyl group, out of the radical polymerizable compounds, include monofunctional (meth)acrylates such as phenoxyethyl (meth)acrylate, 2-methoxyethyl (meth)acrylate, 2-hydroxyethyl (meth)acrylate, benzyl (meth)acrylate, cyclohexyl (meth)acrylate, ethoxydiethylene glycol (meth) acrylate, methoxypolyethylene glycol (meth) acrylate, methyl (meth)acrylate, polyethylene glycol (meth)acrylate, polypropylene glycol (meth)acrylate, and stearyl (meth)acrylate; and

polyfunctional (meth)acrylates such as trimethylolpropane tri(meth)acrylate, pentaerythritol tetra(meth)acrylate, dipentaerythritol hexa(meth)acrylate, diethylene glycol di(meth)acrylate, triethylene glycol di(meth)acrylate, tetraethylene glycol di(meth)acrylate, polyethylene glycol di(meth)acrylate, bis(2-hydroxyethyl)isocyanurate di(meth)acrylate, and 2,2-bis[4-(acryloxy-diethoxy)phenyl]propane. However, the compound having a (meth)acryloyl group is not necessarily limited thereto.

Examples of the compound having a vinyl group include monofunctional vinyl compounds such as monovinylbenzene, and ethylene glycol monovinyl ether; and polyfunctional vinyl compounds such as divinylbenzene, ethylene glycol divinyl ether, diethylene glycol divinyl ether, and triethylene glycol divinyl ether. However, the compound having a vinyl group is not necessarily limited thereto.

One kind of the radical polymerizable compound may be used, and two or more kinds thereof are used together. In the case of making the refractive index of the metal oxide high and making the refractive index of the organic polymer low, in the present invention, a compound having no aromatic group to have low refractive index (for example, refractive index of 1.5 or less) is preferred out of the above-mentioned radical polymerizable compounds. In order to make the compatibility with the metal oxide better, preferred is a more hydrophilic glycol derivative such as polyethylene glycol (meth)acrylate and polyethylene glycol di(meth)acrylate.

The cationic polymerizable compound is not particularly limited about the structure as long as the compound has at least one reactive group selected from a cyclic ether group and a vinyl ether group.

Examples of the compound having a cyclic ether group out of such cationic polymerizable compounds include compounds having an epoxy group, an alicyclic epoxy group or an oxetanyl group.

Specific examples of the compound having an epoxy group include monofunctional epoxy compounds such as 1,2-epoxyhexadecane, and 2-ethylhexyldiglycol glycidyl ether; and polyfunctional epoxy compounds such as bisphenol A diglycidyl ether, novolak type epoxy resins, trisphenolmethane triglycidyl ether, 1,4-butanediol diglycidyl ether, 1,6-hexanediol diglycidyl ether, glycerin triglycidyl ether, trimethylolpropane triglycidyl ether, propylene glycol diglycidyl ether, and polyethylene glycol diglycidyl ether.

Specific examples of the compound having an alicyclic epoxy group include monofunctional compounds such as 1,2-epoxy-4-vinylcyclohexane, D-2,2,6-trimethyl-2,3-epoxybicyclo[3,1,1]heptane, and 3,4-epoxycyclohexylmethyl (meth)acrylate; and polyfunctional compounds such as 2,4-epoxycyclohexylmethyl-3,4-epoxycyclohexane carboxylate, bis(3,4-epoxycyclohexylmethyl) adipate, 2-(3,4-epoxycyclohexyl-5,5-spiro-3,4-epoxy)cyclohexanone-m-dioxane, bis(2,3-epoxycyclopentyl) ether, and EHPE-3150 (alicyclic epoxy resin, manufactured by Dicel Chemical Industries, Ltd.).

Specific examples of the compound having an oxetanyl group include monofunctional oxetanyl compounds such as 3-ethyl-3-hydroxymethyloxetane, 3-ethyl-3-(2-ethylhexyloxymethyl)oxetane, and 3-ethyl-3-(cyclohexyloxymethyl) oxetane; and polyfunctional oxetanyl compounds such as 1,4-bis[(3-ethyl-3-oxetanylmethoxy)methyl]benzene, 1,3-bis[(3-ethyl-3-oxetanylmethoxy)methyl]propane, ethylene glycol bis(3-ethyl-3-oxetanylmethyl) ether, trimethylolpropanetris(3-ethyl-3-oxetanylmethyl) ether, pentaerythritol tetrakis(3-ethyl-3-oxetanylmethyl) ether, dipentaerythritol hexakis (3-ethyl-3-oxetanylmethyl) ether, and ethylene oxide modified bisphenol A bis(3-ethyl-3-oxetanylmethyl) ether.

Specific examples of the compound having a vinyl ether group, out of the above-mentioned cationic polymerizable compounds, include monofunctional compounds such as triethylene glycol monovinyl ether, cyclohexanedimethanol monovinyl ether, and 4-hydroxycyclohexyl vinyl ether; and polyfunctional compounds such as triethylene glycol divinyl ether, tetraethylene glycol divinyl ether, trimethylolpropane trivinyl ether, cyclohexane-1,4-dimethylol divinyl ether, 1,4-butanediol divinyl ether, polyester divinyl ether, and polyurethane polyvinyl ether.

One kind of the cationic polymerizable compound may be used, or two or more kinds thereof may be used together. As the photopolymerizable compound, an oligomer of the cationic polymerizable compounds exemplified above may be used. In the case of making the refractive index of the metal oxide high and making the refractive index of the organic polymer low, in the present invention, a compound having no aromatic group to have low refractive index (for example, refractive index of 1.5 or less) is preferred out of the above-mentioned cationic polymerizable compounds. In order to make the compatibility with the metal oxide better, preferred is a more hydrophilic glycol derivative such as polyethylene glycol diglycidyl ether.

It is advisable that in the present invention the photopolymerizable compound is used, for example, in an amount of about 5 to 1,000% by weight of total of the metal oxide (complex oxide), preferably in an amount of 10 to 300% by weight thereof. If the amount is less than 5% by weight, a large refractive index change is not easily obtained at the time of recording. If the amount is more than 1,000% by weight, a large refractive index change is not easily obtained, either, at the time of recording.

In the present invention, it is preferred that the hologram recording material further contains a photopolymerization initiator corresponding to the wavelength of recording light. When the photopolymerization initiator is contained in the hologram recording material, the polymerization of the photopolymerizable compound is promoted by the light exposure at the time of recording. Consequently, a higher sensitivity is achieved.

When a radical polymerizable compound is used as the photopolymerizable compound, a photo radical initiator is used. On the other hand, when a cationic polymerizable compound is used as the photopolymerizable compound, a cationic photoinitiator is used.

Examples of the photo radical initiator include Darocure 1173, Irgacure 784, Irgacure 651, Irgacure 184 and Irgacure 907 (each manufactured by Ciba Specialty Chemicals Inc.). The content of the photo radical initiator is, for example, about 0.1 to 10% by weight, preferably about 0.5 to 5% by weight on the basis of the radical polymerizable compound.

As the cationic photoinitiator, for example, an onium salt such as a diazonium salt, a sulfonium salt, or an iodonium salt can be used. It is particularly preferred to use an aromatic onium salt. Besides, an iron-arene complex such as a ferrocene derivative, an arylsilanol-aluminum complex, or the like can be preferably used. It is advisable to select an appropriate initiator from these. Specific examples of the cationic photoinitiator include Cyracure UVI-6970, Cyracure UVI-6974 and Cyracure UVI-6990 (each manufactured by Dow Chemical Co. in USA), Irgacure 264 and Irgacure 250 (each manufactured by Ciba Specialty Chemicals Inc.), and CIT-1682 (manufactured by Nippon Soda Co., Ltd.). The content of the cationic photoinitiator is, for example, about 0.1 to 10% by weight, preferably about 0.5 to 5% by weight on the basis of the cation polymerizable compound.

The hologram recording material preferably contains a dye or the like that functions as a photosensitizer corresponding to the wavelength of recording light besides the photopolymerization initiator. Examples of the photosensitizer include thioxanthones such as thioxanthen-9-one, and 2,4-diethyl-9H-thioxanthen-9-one; xanthenes; cyanines; melocyanines; thiazines; acridines; anthraquinones; and squaliriums. It is advisable to set an amount to be used of the photosensitizer into the range of about 3 to about 50% by weight of the radical photoinitiator, for example, about 10% by weight thereof.

In such a way, the hologram recording material layer is produced wherein the photopolymerizable organic compound is uniformly contained in the metal oxide matrix.

The hologram recording medium of the present invention comprises at least the above-mentioned hologram recording material layer. Usually, a hologram recording medium comprises a supporting substrate (i.e., a substrate) and a hologram recording material layer; however, a hologram recording medium may be made only of a hologram recording material layer without having any supporting substrate. For example, a medium composed only of a hologram recording material layer may be obtained by forming the hologram recording material layer onto the substrate by application, and then peeling the hologram recording material layer off from the substrate. In this case, the hologram recording material layer is, for example, a layer having a thickness in the order of millimeters.

The hologram recording medium of the present invention is suitable for record and reproduction using not only a green laser light but also a blue laser light having a wavelength of 350 to 450 nm. When the reproduction is made using transmitted light, the medium preferably has a light transmittance of 50% or more at a wavelength of 405 nm. When the reproduction is made using reflected light, the medium preferably has a light reflectance of 25% or more at a wavelength of 405 nm.

The hologram recording medium is either of a medium having a structure for performing reproduction using transmitted light (hereinafter referred to as a transmitted light reproducing type medium), and a medium having a structure for performing reproduction using reflected light (hereinafter referred to as a reflected light reproducing type medium) in accordance with an optical system used for the medium.

The transmitted light reproducing type medium is constructed in such a manner that a laser light for readout is irradiated into the medium, the laser light irradiated therein is diffracted by signals recorded in its hologram recording material layer, and the laser light transmitted through the medium is converted to electric signals by means of an image sensor. In other words, in the transmitted light reproducing type medium, the laser light to be detected is transmitted through the medium toward the medium side opposite to the medium side into which the reproducing laser light is incident. The transmitted light reproducing type medium usually has a structure wherein its recording material layer is sandwiched between two supporting substrates. In an optical system used for the medium, the image sensor, for detecting the transmitted laser light, is set up in the medium side opposite to the medium side into which the reproducing laser light emitted from a light source is irradiated.

Accordingly, in the transmitted light reproducing type medium, the supporting substrate, the recording material layer, and any other optional layer(s) are each made of a light-transmitting material. It is unallowable that any element blocking the transmission of the reproducing laser light is substantially present. The supporting substrate is usually a rigid substrate made of glass or resin.

In the meantime, the reflected light reproducing type medium is constructed in such a manner that a laser light for readout is irradiated into the medium, the laser light irradiated therein is diffracted by signals recorded in the hologram recording material layer, and then, the laser light is reflected on a reflective film, and the reflected laser light is converted to electric signals by means of an image sensor. In other words, in the reflected light reproducing type medium, the laser light to be detected is reflected toward the same medium side as the medium side into which the reproducing laser light is incident. The reflected light reproducing type medium usually has a structure wherein the recording material layer is formed on a supporting substrate positioned at the medium side into which the reproducing laser light is irradiated; and a reflective film and an another supporting substrate are formed on the recording material layer. In an optical system used for the medium, the image sensor, for detecting the reflected laser light, is set up in the same medium side as the medium side into which the reproducing laser light emitted from a light source is irradiated.

Accordingly, in the reflected light reproducing type medium, the supporting substrate positioned at the medium surface side into which the reproducing laser light is irradiated, the recording material layer, and other optional layer(s) positioned nearer to the medium side into which the reproducing laser light is irradiated than the reflective film are each made of a light-transmitting material. It is unallowable that these members each substantially contain an element blocking the incident or reflective reproducing laser light. The supporting substrate is usually a rigid substrate made of glass or resin. The supporting substrate positioned at the medium surface side into which the reproducing laser light is irradiated is required to have a light-transmitting property.

In any case of the transmitted light reproducing type medium and the reflected light reproducing type medium, it is important that the hologram recording material layer has a high light transmittance of, for example, 50% or more at a wavelength of 405 nm. For example, in the case of considering a layer (100 μm in thickness) composed only of the matrix material (metal oxide material) ,it is preferred that the layer has a high light transmittance of 90% or more at a wavelength of 405 nm.

The hologram recording material layer obtained as above-mentioned has a high transmittance to a blue laser. Therefore, even if a thickness of the recording material layer is set to 100 μm, a recording medium having a light transmittance of 50% or more, preferably 55% or more at a wavelength of 405 nm is obtained when the medium is a transmitted light reproducing type medium; or a recording medium having a light reflectance of 25% or more, preferably 27.5% or more at a wavelength of 405 nm is obtained when the medium is a reflected light reproducing type medium. In order to attain holographic memory recording characteristics such that a high multiplicity is ensured, necessary is a recording material layer having a thickness of 100 pm or more, preferably 200 μm or more. According to the present invention, however, even if the thickness of the recording material layer is set to, for example, 1 mm, it is possible to ensure a light transmittance of 50% or more at a wavelength of 405 nm (when the medium is a transmitted light reproducing type medium), or a light reflectance of 25% or more at a wavelength of 405 nm (when the medium is a reflected light reproducing type medium).

When the above described hologram recording material layer is used, a hologram recording medium having a recording layer thickness of 100 μm or more, which is suitable for data storage, can be obtained. The hologram recording medium can be produced by forming the hologram recording material in a film form onto a substrate, or sandwiching the hologram recording material in a film form between substrates.

In a transmitted light reproducing type medium, it is preferred to use, for the substrate(s), a material transparent to a recording/reproducing wavelength, such as glass or resin. It is preferred to form an anti-reflection film against the recording/reproducing wavelength for preventing noises or give address signals and so on, onto the substrate surface at the side opposite to the layer of the hologram recording material. In order to prevent interface reflection, which results in noises, it is preferred that the refractive index of the hologram recording material and that of the substrate are substantially equal to each other. It is allowable to form, between the hologram recording material layer and the substrate, a refractive index adjusting layer comprising a resin material or oil material having a refractive index substantially equal to that of the recording material or the substrate. In order to keep the thickness of the hologram recording material layer between the substrates, a spacer suitable for the thickness between the substrates may be arranged. End faces of the recording material medium are preferably subjected to treatment for sealing the recording material.

About the reflected light reproducing type medium, it is preferred that the substrate positioned at the medium surface side into which a reproducing laser light is irradiated is made of a material transparent to a recording and reproducing wavelength, such as glass or resin. As the substrate positioned at the medium surface side opposite to the medium surface side into which a reproducing laser light is irradiated, a substrate having thereon a reflective film is used. Specifically, a reflective film made of, for example, Al, Ag, Au or an alloy made mainly of these metals and the like is formed on a surface of a rigid substrate (which is not required to have a light-transmitting property), such as glass or resin, by vapor deposition, sputtering, ion plating, or any other film-forming method, whereby a substrate having thereon the reflective film is obtained. A hologram recording material layer is provided so as to have a predetermined thickness on the surface of the reflective film of this substrate, and further a light- transmitting substrate is caused to adhere onto the surface of this recording material layer. An adhesive layer, a flattening layer and the like may be provided between the hologram recording material layer and the reflective film, and/or between the hologram recording material layer and the light-transmitting substrate. It is also unallowable that these optional layers hinder the transmission of the laser light. Others than this matter are the same as in the above-mentioned transmitted light reproducing type medium.

### EXAMPLES

The present invention will be more specifically described by way of the following examples; however, the present invention is not limited to these examples.

### Example 1

### Preparation of Complex Oxide Sol

In 6 mL of 1-methoxy-2-propanol solvent, 5.815 g of titanium tetraisopropoxide (Ti(OiPr)₄, manufactured by AZmax Co., Ltd.) and 4.32 g of diphenyldisilanol (Ph₂Si(OH)₂, manufactured by Shin-Etsu Chemical Co., Ltd.) were mixed at room temperature. Then, the mixture was stirred at 80° C. for 1 hour to give a mixed liquid. Ti/Si=1/1 (molar ratio). The mixed liquid was cooled to room temperature.

To the mixed liquid, 0.74 mL of water and 1.5 mL of 1-methoxy-2-propanol were added with stirring at room temperature and continued to be stirred for 3 hours, thereby being subjected to a hydrolysis reaction and a condensation reaction. Thus, a sol solution was obtained.

About the resultant sol solution, a particle diameter was measured by a dynamic light scattering method. As a result, the mode value in the particle size distribution was about 4 nm. The measurement was made with a device (trade name: ZETASIZER Nano-ZS) manufactured by Sysmex.

### Comparative Example 1

To 5.0 g diphenyldimethoxysilane (Ph₂Si(OMe)₂, manufactured by Shin-Etsu Chemical Co., Ltd.), a solution composed of 0.37 mL of water, 0.15 mL of a 2N aqueous hydrochloric acid solution and 5 mL of a solvent, 1-methoxy-2-propanol, was added dropwise with stirring at room temperature and continued to be stirred for 3 hours, thereby being subjected to a hydrolysis reaction. Subsequently, 5.815 g of titanium tetraisopropoxide (Ti(OiPr)₄, manufactured by AZmax Co., Ltd.) was added to this reaction liquid and then stirred at 80° C. for 1 hour to give a mixed liquid. Ti/Si=1/1 (molar ratio). The mixed liquid was cooled to room temperature.

To the mixed liquid, 0.74 mL of water and 1.5 mL of 1-methoxy-2-propanol were added with stirring at room temperature and continued to be stirred for 1 hour, thereby being further subjected to a hydrolysis reaction and a condensation reaction. Thus, a sol solution was obtained.

About the resultant sol solution, a particle diameter was measured by a dynamic light scattering method. As a result, the mode value in the particle size distribution was about 6 nm.

### Example 2

### Production of Hologram Recording Medium

### (Synthesis of Matrix Material)

In 6 mL of methoxypropanol solvent, 5.815 g of titanium tetraisopropoxide (Ti(OiPr)₄, manufactured by AZmax Co., Ltd.) and 4.32 g of diphenyldisilanol (Ph₂Si(OH)₂, manufactured by Shin-Etsu Chemical Co., Ltd.) were mixed at room temperature. Then, the mixture was stirred at 80° C. for 1 hour to give a mixed liquid. Ti/Si=1/1 (molar ratio). The mixed liquid was cooled to room temperature.

To the mixed liquid, 0.74 mL of water and 1.5 mL of 1-methoxy-2-propanol were added with stirring at room temperature and continued to be stirred for 1 hour, thereby being subjected to a hydrolysis reaction and a condensation reaction. Thus, a sol solution was obtained.

### (Photopolymerizable Compound)

To 100 parts by weight of polyethylene glycol monoacrylate (130A, manufactured by KYOEISHA CHEMICAL Co., LTD) as a photopolymerizable compound were added 3 parts by weight of a photopolymerization initiator (IRG-907, manufactured by Ciba Specialty Chemicals K.K.) and 0.3 part by weight of 2,4-diethyl-9H-thioxanthen-9-one as a photosensitizer to prepare a mixture containing the photopolymerizable compound.

### (Hologram Recording Material)

The sol solution and the mixture containing the photopolymerizable compound were mixed with each other at a room temperature to set the ratio of the matrix material (as a nonvolatile component) and that of the photopolymerizable compound to 85 parts by weight and 15 parts by weight respectively. Furthermore, the sol-gel reaction was sufficiently advanced for 1 hour in a state that light was shielded from the system, so as to yield a hologram recording material liquid.

The resultant hologram recording material liquid was applied onto a glass substrate and then dried to prepare a recording medium sample, as will be detailed below.

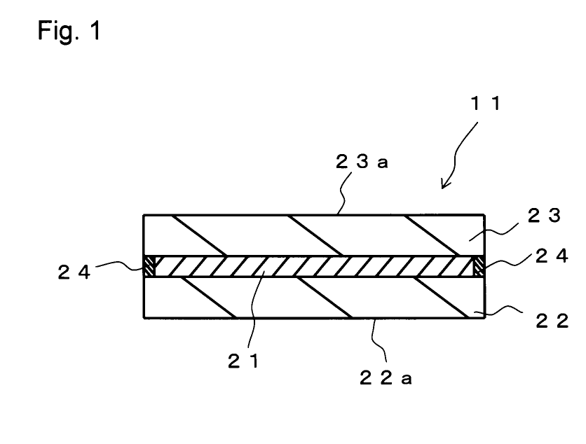

With reference to FIG. 1, which schematically illustrates a cross section of a hologram recording medium, explanation will be described.

A glass substrate (22) having a thickness of 1 mm and having one surface on which an anti-reflection film (22a) was formed was prepared. A spacer (24) having a predetermined thickness was put on a surface of the glass substrate (22) on which the anti-reflection film (22a) was not formed, and the hologram recording material liquid obtained was applied onto the surface of the glass substrate (22). The resultant was dried at a room temperature for 1 hour, and then dried at 40° C. for 24 hours to volatilize the solvent. Through this drying step, the gelation (condensation reaction) of the metal oxide (complex oxide) was advanced so as to yield a hologram recording material layer (21) having a dry film thickness of 140 μm wherein the metal oxide (complex oxide) and the photopolymerizable compound were uniformly dispersed.

### (Hologram Recording Medium)

The hologram recording material layer (21) formed on the glass substrate (22) was covered with another glass substrate (23) having a thickness of 1 mm and having one surface on which an anti-reflection film (23a) was formed. At this time, the covering was carried out in such a manner that a surface of the glass substrate (23) on which the anti-reflection film (23a) was not formed would contact the surface of the hologram recording material layer (21). In this way, a hologram recording medium (11) was obtained which had a structure wherein the hologram recording material layer (21) was sandwiched between the two glass substrates (22) and (23).

### (Evaluation of Characteristics)

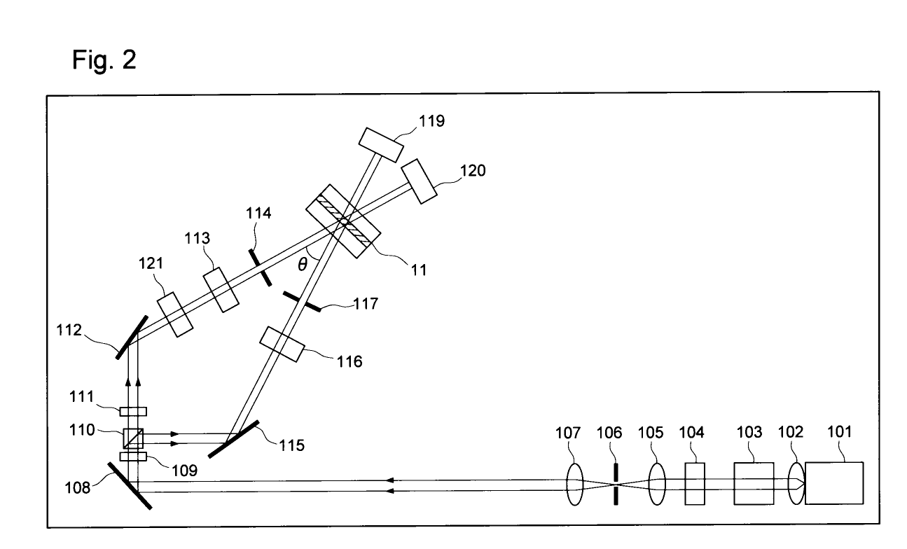

About the resultant hologram recording medium sample, characteristics thereof were evaluated in a hologram recording optical system as illustrated in FIG. 2. The direction along which the paper surface on which FIG. 2 is drawn stretches is defined as a horizontal direction for convenience' sake.

In FIG. 2, the hologram recording medium sample (11) was set to make the recording material layer perpendicular to the horizontal direction.

In the hologram recording optical system illustrated in FIG. 2, a light source (101) for emitting a semiconductor laser (wavelength: 405 nm) in a single mode oscillation was used. Light emitted from this light source (101) was subjected to a spatial filtrating treatment by means of a beam shape adjuster (102), a light isolator (103), a shutter (104), a convex lens (105) , a pinhole (106) , and a convex lens (107), so as to be collimated, thereby enlarging the light into a beam diameter of about 10 mmφ. The enlarged beam was passed through a mirror (108) and a 1/2 wavelength plate (109) to take out 45°(45 degree) polarized light. The light was split into an S wave and a P wave (the ratio of S wave/P wave is 1/1) through a polarized beam splitter (110). The S wave obtained by the splitting was passed through a mirror (115), a polarizing filter (116) , and an iris diaphragm (117) , while a 1/2 wavelength plate (111) was used to convert the P wave obtained by the splitting to an S wave and then the S wave was passed through a mirror (112) , a polarizing filter (113) and an iris diaphragm (114). In this way, the total incident angle θ of the two light fluxes irradiated into the hologram recording medium sample (11) was set to 37°, so as to record interference fringes of the two light fluxes in the sample (11).

The sample (11) was rotated in the horizontal direction to attain multiplexing (angle multiplexing; sample angle: −21° to +21°, angle interval: 1.5° ), thereby attaining hologram recording. The multiplicity was 29. At the time of recording, the sample was exposed to the light while the iris diaphragms (114) and (117) were each set to a diameter of 4 mm. At a position where the angle of the surfaces of the sample (11) to the bisector (not illustrated) of the angle θ made by the two light fluxes was 90°, the above-mentioned sample angle was set to ±0.

After the hologram recording, in order to react remaining unreacted components, a sufficient quantity of blue light having a wavelength of 400 nm was irradiated to the whole of the surface of the sample (11) from a blue LED. At this time, the light was irradiated through an acrylic resin diffuser plate having a light transmittance of 80% so as to cause the irradiated light not to have coherency (the light irradiation is called post-cure). At the time of reproduction, with shading by the shutter (121), the iris diaphragm (117) was set into a diameter of 1 mm and only one light flux was irradiated. The sample (11) was continuously rotated into the horizontal direction from −23° to +23°. In the individual angle positions, the diffraction efficiency was measured with a power meter (120). When a change in the volume (a recording shrinkage) or a change in the average refractive index of the recording material layer is not generated before and after the recording, the diffraction peak angle in the horizontal direction at the time of the recording is consistent with that at the time of the reproduction. Actually, however, a recording shrinkage or a change in the average refractive index is generated; therefore, the diffraction peak angle in the horizontal direction at the time of the reproduction is slightly different from the diffraction peak angle in the horizontal direction at the time of the recording. For this reason, at the time of the reproduction, the angle in the horizontal direction was continuously changed and then the diffraction efficiency was calculated from the peak intensity when a diffraction peak made its appearance. In FIG. 2, reference number (119) represents a power meter not used in this example.

At this time, a dynamic range M/# (the sum of the square roots of the diffraction efficiencies) was a value of 22.0, which was a converted value corresponding to the case that the thickness of the hologram recording material layer was converted to 1 mm. A light transmittance of the medium (recording layer thickness: 140 μm) before the exposure of recording light (at the initial stage) was 93.1% at 405 nm.

At this time, a reduction ratio in the light transmittance on the basis of the glass substrates (22) and (23) each having the anti-reflection film was 0.6%. Specifically, with reference to FIG. 1, a laser light was irradiated into the sample (11) from the side of the substrate (22) , so as to be transmitted toward the side of the substrate (23); in this case, 0.3% of the light was reflected on the interface between the air and the anti-reflection film (22a) by the presence of the anti-reflection film (22a), and 99.7% thereof was transmitted (absorption: 0%), and 0.3% of the transmitted light (that is, 99.7%) was reflected on the interface between the anti-reflection film (23a) of the substrate (23) and the air. As a result, 99.4% of the original laser light was transmitted.

The refractive index of the glass substrates (22) and (23) was substantially equal to that of the hologram recording material layer (21) ; therefore, reflection on the interface between the glass substrate (22) and the recording material layer (21) and reflection on the interface between the recording material layer (21) and the glass substrate (23) may be neglected.

### Example 3

### Production of Hologram Recording Medium

(Synthesis of matrix material) In 1 mL of n-butanol solvent, 3.65 g of titanium tetra-n-butoxide (Ti (OBu)₄, manufactured by Kojundo Chemical Laboratory Co., Ltd.) and 2.52 g of 2-methylpentane-2,4-diol (manufactured by Tokyo Chemical Industry Co., Ltd.) were mixed at room temperature and stirred for 10 minutes. Ti(OBu)₄/2-methylpentane-2,4-diol=1/2 (molar ratio). 1.16 g of diphenyldisilanol (Ph₂Si(OH)₂, manufactured by Shin-Etsu Chemical Co., Ltd.) was mixed to this reaction liquid at room temperature and then stirred at 80° C. for 1 hour to give a mixed liquid. Ti/Si=2/1 (molar ratio). The mixed liquid was cooled to room temperature.

To the mixed liquid, 0.15 mL of water and 1 mL of ethanol were added with stirring at room temperature and continued to be stirred for 1 hour, thereby being subjected to a hydrolysis reaction and a condensation reaction. Thus, a sol solution was obtained.

In the same manner as in Example 2, the resultant sol solution and the mixture containing the photopolymerizable compound were mixed with each other at a room temperature. In the state that the system was shielded from light, the sol-gel reaction was sufficiently advanced for 1 hour to yield a hologram recording material liquid. The resultant hologram recording material liquid was applied onto the substrate in the same manner as in Example 2 to yield a hologram recording material layer (21) having a dry film thickness of 165 μm. In this way, a hologram recording medium (11) was obtained.

Characteristics thereof were evaluated in the same manner as in Example 2. As a result, a dynamic range M/# was a value of 10.0, which was a converted value corresponding to the case that the thickness of the hologram recording material layer was converted to 1 mm. A light transmittance of the medium (recording layer thickness: 165 μm) before the exposure of recording light (at the initial stage) was 86.2% at 405 nm.

### Example 4

### Production of Hologram Recording Medium

### (Synthesis of Matrix Material)

In 1 mL of n-butanol solvent, 3.65 g of titanium tetra-n-butoxide (Ti(OBu)₄, manufactured by Kojundo Chemical Laboratory Co., Ltd.) and 2.52 g of 2-methylpentane-2,4-diol (manufactured by Tokyo Chemical Industry Co., Ltd.) were mixed at room temperature and stirred for 10 minutes. Ti(OBu)₄/2-methylpentane-2,4-diol=1/2 (molar ratio). 2.33 g of diphenyldisilanol (Ph₂Si(OH)₂, manufactured by Shin-Etsu Chemical Co., Ltd.) was mixed to this reaction liquid at room temperature and then stirred at 80° C. for 1 hour to give a mixed liquid. Ti/Si=1/1 (molar ratio). The mixed liquid was cooled to room temperature.

To the mixed liquid, 0.15 mL of water and 1 mL of ethanol were added with stirring at room temperature and continued to be stirred for 1 hour, thereby being subjected to a hydrolysis reaction and a condensation reaction. Thus, a sol solution was obtained.

In the same manner as in Example 2, the resultant sol solution and the mixture containing the photopolymerizable compound were mixed with each other at a room temperature. In the state that the system was shielded from light, the sol-gel reaction was sufficiently advanced for 1 hour to yield a hologram recording material liquid. The resultant hologram recording material liquid was applied onto the substrate in the same manner as in Example 2 to yield a hologram recording material layer (21) having a dry film thickness of 138 μm. In this way, a hologram recording medium (11) was obtained.

Characteristics thereof were evaluated in the same manner as in Example 2. As a result, a dynamic range M/# was a value of 40.0, which was a converted value corresponding to the case that the thickness of the hologram recording material layer was converted to 1 mm. A light transmittance of the medium (recording layer thickness: 138 μm) before the exposure of recording light (at the initial stage) was 83.0% at 405 nm.

What is claimed is:

1. A method for producing a complex oxide sol comprising Si and a metal other than Si as metal elements, the method comprising:
mixing a silanol compound with an alkoxide compound of a metal other than Si so that the silanol compound is reacted with the alkoxide compound, thereby yielding a precursor of a complex oxide, and
adding water to the complex oxide precursor so as to hydrolyze an alkoxyl group bonded to the metal other than Si, and then making the resulting hydrolysate undergo a condensation reaction, thereby forming a complex oxide.

2. The method for producing the complex oxide sol according to claim 1, wherein the metal other than Si is selected from the group consisting of Ti, Zr, Ta, Sn, Zn and Al.

3. The method for producing the complex oxide sol according to claim 1, wherein neither acid catalyst nor alkaline catalyst is used during the hydrolysis.

4. The method for producing the complex oxide sol according to claim 1, wherein the silanol compound is represented by the following general formula (I):
(R₁)(R₂)Si(OH)₂ (I)
wherein R₁ and R₂ may be the same or different and each represents an alkyl group which may have a substituent or an aryl group which may have a substituent, provided that at least one of the R₁ and the R₂ is an aryl group which may have a substituent.

5. The method for producing the complex oxide sol according to claim 1, the method further comprising:
coordinating a complexing ligand to the alkoxide compound of the metal other than Si,
before the mixing of the silanol compound with the alkoxide compound of the metal other than Si, or after the mixing of the silanol compound with the alkoxide compound of the metal other than Si and before the addition of water.

6. A complex oxide sol comprising Si and a metal other than Si as metal elements,
wherein the complex oxide sol is obtained by a method comprising:
mixing a silanol compound with an alkoxide compound of a metal other than Si so that the silanol compound is reacted with the alkoxide compound, thereby yielding a precursor of a complex oxide, and
adding water to the complex oxide precursor so as to hydrolyze an alkoxyl group bonded to the metal other than Si, and then making the resulting hydrolysate undergo a condensation reaction, thereby forming a complex oxide.

7. A method for producing a hologram recording material comprising metal oxide fine particles containing an organic group and a photopolymerizable compound, the method comprising:
mixing a silanol compound with an alkoxide compound of a metal other than Si so that the silanol compound is reacted with the alkoxide compound, thereby yielding a precursor of a complex oxide,
adding water to the complex oxide precursor so as to hydrolyze an alkoxyl group bonded to the metal other than Si, and then making the resulting hydrolysate undergo a condensation reaction, thereby forming a complex oxide, and
mixing a photopolymerizable compound before, during or after the hydrolysis.

8. The method for producing the hologram recording material according to claim 7, wherein the silanol compound is represented by the following general formula (I):
(R₁)(R₂)Si(OH)₂ (I)
wherein R₁ and R₂ may be the same or different and each represents an alkyl group which may have a substituent or an aryl group which may have a substituent, provided that at least one of the R₁ and the R₂ is an aryl group which may have a substituent.

9. A hologram recording medium having a hologram recording layer comprising the hologram recording material obtained by the production method according to claim 7.

10. The hologram recording medium according to claim 9, wherein record/reproduction of the hologram recording medium are performed by use of a laser light having a wavelength of 350 to 450 nm.
